(19) United States
(12) Patent Application Publication
(10) Pub. No.: US 2024/0206615 A1
(43) Pub. Date: Jun. 27, 2024

(54) Method and Related Systems for Manufacturing Shaving Stencils

(71) Applicant: Zaher AKAHSHLI, Surrey (CA)

(72) Inventor: Zaher AKAHSHLI, Surrey (CA)

(21) Appl. No.: 18/287,311

(22) PCT Filed: Apr. 25, 2022
(86) PCT No.: PCT/CA2022/050627

§ 371 Date: Oct. 18, 2023

(51) Int. Cl. A45D 24/36; G06F 30/17

(52) U.S. Cl. CPC A45D 24/36; G06F 30/17

(57) ABSTRACT

The present disclosure provides a method of manufacturing one or more shaving stencils automatically based on a library of 3D models of human and animal body parts. The shaving stencils can be made according to a standard specification for a human or animal body part or according to a desired specification set out in a stencil request. Systems for implementing the disclosed method are also provided, including a mobile application configured to scan a user's face and provide an interface for viewing certain pre-made stencils on the scanned face.

### CROSS REFERENCES TO RELATED APPLICATIONS

The present application claims the benefit and priority of U.S. provisional application No. 63/180,126, filed Apr. 27, 2021.

### FIELD OF INVENTION

The present invention relates generally to automating the manufacture of shaving stencils. More specifically, the present invention relates to a method of overlaying a design on a 3D representation of a body part of a human or animal, converting the representation to 2D and manufacturing the resultant design as a stencil.

### BACKGROUND

In recent years, trends for shaving facial and body hair into short cut, sharply defined, aesthetically appealing patterns have grown in popularity. These patterns are often shaven into facial hair but they are applied to other areas as well including, for example, pubic hair.

While aesthetically appealing, the maintenance of such hairstyles can be difficult to maintain. In order to ensure they are cut properly an individual will usually go to a professional barber to have them cut, and as the patterns require areas of short hair and areas of no hair at all in order to clearly define the patterns, frequent trips are often required which can be expensive. Furthermore, for areas such as pubic hair some individuals may be embarrassed to have another person applying the patterns.

Shaving stencils are known tools that go some way towards solving these issues by providing an overlay that covers a pre-defined pattern of an individual's hair. Shaving stencils often comprise a rigid plastic cover shaped in a pre-defined pattern which needs to be held against a user's face. Ultimately, these tools are more useful for professional barber's than as a tool for the actual end user. Known shaving stencil products are also severely limited in the variety of styles available and body parts to which they can be applied.

U.S. Pat. No. 10,646,016B2 describes a hair grid measuring device that comprises a thin, flexible body, a first side opposite a second side, a third side opposite a fourth side, a plurality of horizontal grid lines extending from the first side to the second side, and a plurality of vertical grid lines extending from the third side to the fourth side. The thin, flexible body also includes a plurality of apertures holding the device against a first individual's skin, ensuring stability and leverage, and easily bending the grid measuring device to the contours of the first individual's face, head, and body. It also discloses a method for creating a custom hair style using the hair grid measuring device, accomplished either by hand or via a software application on an electronic device, that allows the first individual to obtain the hair design of a second individual, such as a celebrity, sports player, or actor, or any predetermined shape.

The hair grid measuring device and method of creation thereof are once more, ultimately more useful for professional barbers with training and experience of how to use such items to actually cut an individual's hair. Furthermore, such methods are not suitable for all body areas.

There is therefore a need for a way of easily creating shaving stencils for various human and animal body parts and that may be used by an individual with no professional training or experience in hair cutting. It is within this context that the present invention is provided.

### SUMMARY

The present disclosure provides a method of manufacturing one or more shaving stencils automatically based on a library of 3D models of human and animal body parts. The shaving stencils can be made according to a standard specification for a human or animal body part or according to a desired specification set out in a stencil request. Systems for implementing the disclosed method are also provided, including a mobile application configured to scan a user's face and provide an interface for viewing certain pre-made stencils on the scanned face.

Thus, according to one aspect of the present disclosure there is provided a method of manufacturing one or more shaving stencils, the method comprising the steps of: creating a library of 3D models or representations of various human or animal body parts; selecting a desired body part to create a stencil for; designing a 3D stencil shaped to create a desired hair pattern for that body part; applying the 3D stencil to the 3D representation of the selected body part; unwrapping the 3D stencil to 2D using UV unwrapping to determine one or more 2D stencil shapes; and printing or cutting the one or more 2D shapes using a flexible substrate to create one or more shaving stencils.

According to another aspect of the present disclosure there is provided a method of manufacturing one or more custom shaving stencils, the method comprising the steps of: receiving a stencil request for one or more custom shaving stencils, the stencil request including target body area data and desired pattern data; generating a 3D model representing the target body area based on the stencil request; overlaying one or more desired patterns to the 3D model based on the stencil request; applying a transformation to the overlaid target body area to determine one or more 2D shapes for the one or more desired patterns; and printing or cutting the one or more 2D shapes using a flexible substrate to create one or more custom shaving stencils.

In one embodiment, the target body area data comprises an indication of a type of human or animal body and an area of the body, and wherein generating the 3D model involves matching the data with a 3D representation stored in a library and using the matched 3D representation to generate the model.

In another embodiment, the target body area data in the stencil request comprises a 3D scan of a human or animal body part, and wherein generating the 3D model involves using the 3D scan to generate the model.

Furthermore, the method may further comprise scanning a body part of a human or animal body to determine a set of contours to include in the stencil request, an optionally comprises adding each scanned body part to a library of 3D models.

In some embodiments, the method further comprises determining a point on the one or more 2D shapes and printing one or more markings on the custom shaving stencils corresponding to the points on the one or more 2D shapes.

Additionally, the determination of where to print the markings may be based on a target point on the 3D model of the target body area.

In some embodiments, the step of applying a transformation to convert the model to 2D comprises a UV unwrapping operation.

In some embodiments, the step of printing or cutting the 2D shapes is a cutting operation performed by a CNC cutting machine.

In further embodiments, the flexible substrate comprises an adhesive layer.

In yet further embodiments, the flexible substrate comprises a layer storing one or more dyes or colouring agents.

According to another aspect of the present disclosure there is provided a virtual representation of a hair pattern created through the use of a 3D stencil or 2D stencil in the above-described embodiments.

Use of the virtual representation to represent a hair pattern on an avatar is also provided.

### BRIEF DESCRIPTION OF THE DRAWINGS

Various embodiments of the invention are disclosed in the following detailed description and accompanying drawings.

FIG. 1 illustrates a flow diagram of a set of steps forming a method of manufacture of a standard shaving stencil according to the present disclosure.

FIG. 2 illustrates an example 3D model of a human face and an example desired pattern overlaid on the 3D model which has been requested as a custom shaving stencil.

FIG. 3 illustrates the example 3D model and desired pattern of FIG. 2 having been transformed into a 2D shape to determine the shape of a stencil for printing.

FIG. 4 illustrates an example 3D model of a horse body and a subsequent 2D transformation obtained via UV unwrapping.

FIG. 5 illustrates a flow diagram of a set of steps forming a method of manufacture of a custom shaving stencil according to the present disclosure.

FIG. 6 illustrates an example configuration of a wireless network architecture over which a client device may request a custom shaving stencil manufactured according to the disclosed method.

FIG. 7 illustrates an example configuration of a wireless device for use with a dedicated application software for sending such a request.

Common reference numerals are used throughout the figures and the detailed description to indicate like elements. One skilled in the art will readily recognize that the above figures are examples and that other architectures, modes of operation, orders of operation, and elements/functions can be provided and implemented without departing from the characteristics and features of the invention, as set forth in the claims.

### DETAILED DESCRIPTION AND PREFERRED EMBODIMENT

The following is a detailed description of exemplary embodiments to illustrate the principles of the invention. The embodiments are provided to illustrate aspects of the invention, but the invention is not limited to any embodiment. The scope of the invention encompasses numerous alternatives, modifications and equivalent; it is limited only by the claims.

Numerous specific details are set forth in the following description in order to provide a thorough understanding of the invention. However, the invention may be practiced according to the claims without some or all of these specific details. For the purpose of clarity, technical material that is known in the technical fields related to the invention has not been described in detail so that the invention is not unnecessarily obscured.

The terminology used herein is for the purpose of describing particular embodiments only and is not intended to be limiting of the invention. As used herein, the term “and/or” includes any combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

The present disclosure relates to a method of manufacturing one or more shaving stencils, preferably in the form of an adhesive sticker which may be placed by a user over a hairy body area of a human or animal, allowing an electric shaver to easily shave the reverse of a pattern shaped by the stencil onto the hairy body area.

Application of hair removal cream over the stencils could achieve a similar effect and therefore any reference in the present application to shaving the area about one or more shaving stencils should also be interpreted as an option that could also involve the application of hair removal cream instead.

The method is flexible and versatile and can be applied to shave any body area and to any type of animal, including facial hair, pubic hair, humans, and domesticated animals.

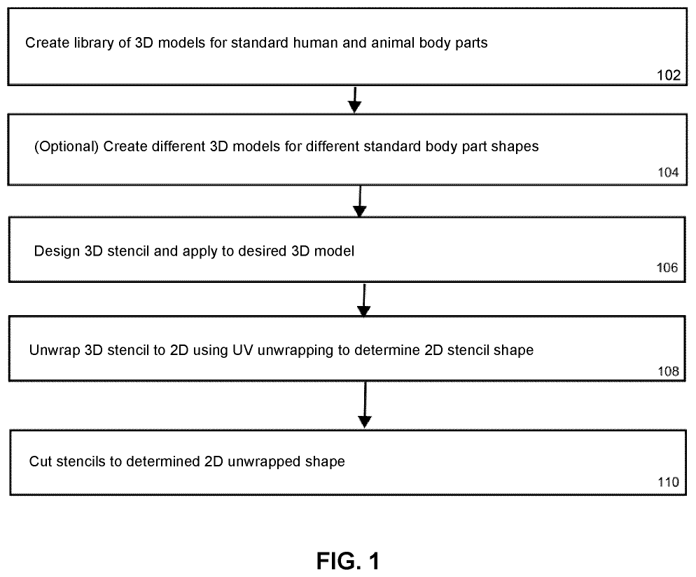

Referring to FIG. 1, a flow diagram is shown of a set of steps forming a method of manufacture of a standard shaving stencil according to the present disclosure.

In a first step 102, a library of 3D models of human and animal body parts is created, this could be based on actual 3D scans or any other kind of 3D modelling. Each model is a mesh or 3D point cloud that allows the 3D contours of that particular body part to be determined.

In a second, optional step 104, models may be created of different types of animal and body parts in the library including different sizes and shapes.

For example, the standard human face and head shapes may be a set of models in the library including main 7 basic face shapes (oval, round, square, diamond, heart, pear and oblong) with every shape available in multiples sizes, for example 2 to 3 sizes, including the standard size circumference to be 55 cm (21¾) in females and 57 cm (22½ in) in males.

In a third step 106, a stencil pattern is designed for creation and applied to a 3D representation of a human or animal body part from the library of 3D models in order to create a stencil having that design and specifically shaped and sized for application to that body part.

This stencil pattern can be in any desired shape. For example, a flame shaped stencil may be created for application to a horse body part such as the flank. In another example a standard beard shaped stencil may be applied to an oval shaped human face 3D model of a given size.

The pattern of the stencil is overlaid in 3D on the model and adopts the 3D contours of the model.

In a fourth step 108, the 3D stencil design is unwrapped into a flat 2D shape using any suitable UV unwrapping process, unfolding the mesh to create a 2D texture which will fit a 3D object profile with the same 3D shape as the original model.

A UV map is the flat representation of the surface of a 3D model used to easily wrap textures. The process of creating a UV map is called UV unwrapping.

The U and V refer to the horizontal and vertical axes of the 2D space, as X, Y and Z are already being used in the 3D space.

Once the polygonal mesh has been created the next step is to “unwrap it” into a UV map.

Finally, in a fifth step 110, the stencil 2D design shape determined in the fourth step is cut out.

The method thus involves printing or cutting the one or more 2D shapes using a flexible substrate to create one or more standard shaving stencils. For example, the determined shape for the requested stencil may be cut out by a CNC machine.

Preferably, the stencil is cut out of a flexible substrate comprising a hair-friendly adhesive layer that can adhere the stencil to the target body area during shaving without requiring pressure to be maintained to hold it in place.

The more human and animal body parts that stencils are generated for, the larger the number of 3D models in the library, meaning that the process becomes more efficient as it is repeated more.

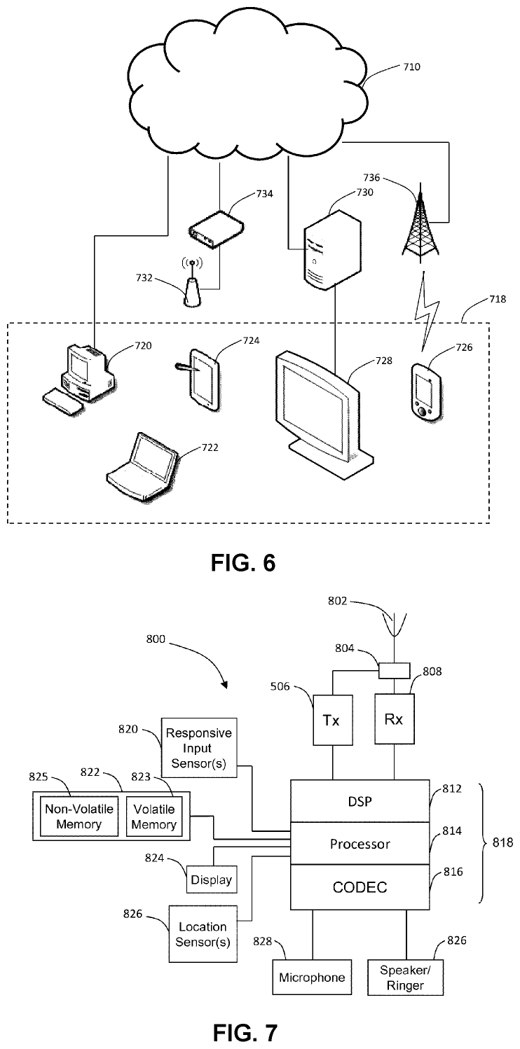

As will be described in relation to FIGS. 6 and 7, systems for an online store and mobile phone application are also provided for allowing end users to check what a stencil from a shop/library of stencil designs would look like on their face. All generated pre-made stencil designs which are available will be uploaded to the store library and stored on the cloud.

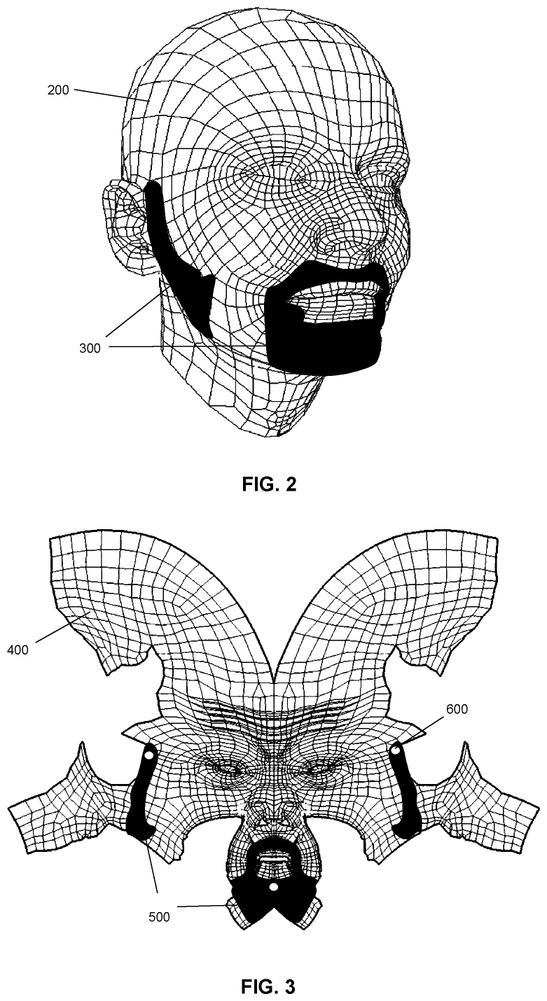

Referring to FIG. 2, an example 3D model of a man's head 200 is shown having a desired stencil pattern for a facial hair shaving stencil comprising a 3D representation of a beard shaping stencil and sideburn shaping stencils 300 applied over its surface.

This is merely an illustrative example and as previously mentioned the method may be applied to any target body area of any human or animal, and any type of shape may be applied. Even exotic shapes such as a logo may be manufactured according to the disclosed method.

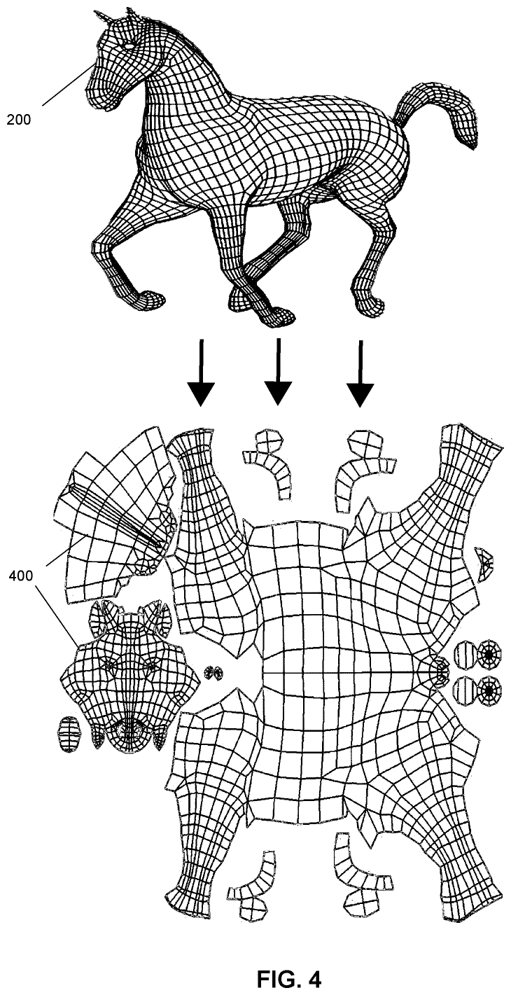

Referring to FIG. 3, a transformed 2D representation of the 3D model and stencil pattern of FIG. 2 is shown. As can be seen, the 2D representation 400 of the same man's head has been flattened out to a planar shape having the same surface area as the original 3D representation.

Similarly, the stencil has been flattened out into a flattened beard stencil shape and two flattened sideburn stencil shapes 500, which also have equal surface area to the original 3D representations.

By applying this transformation, the 2D shapes which need to be cut out in order to fit the 3D target body area have been determined and can be sent to a cutting/printing machine.

Additionally, sets of guide markings 600 have been applied to the 2D stencil shapes to help guide the user in where to place/orient the stencils when applying them to the target body area.

These guide markings 600 can be applied to any clearly marked feature point of a representation of a human or animal body, such as for example the cheekbone of an oval shaped human face or the top of the front shoulder of a horse. When a stencil is applied over the feature point, the mark transfers to the relevant point on the stencil which is then printed, and can allow a user to correctly align the feature point on the stencil with the intended feature point position on the human or animal body.

Referring to FIG. 4, an example 3D model of a horse body 200 and a subsequent 2D transformation 400 of the horse body obtained via a UV unwrapping operation is shown.

Any design can be put on the 3D representation of the horse and transformed into a stencil in exactly the same way as the UV unwrap process illustrated on the face of the man as shown in FIGS. 2 and 3.

According to another embodiment of the present disclosure, instead of pre-made stencil, custom shaving stencil requests can be received and processed.

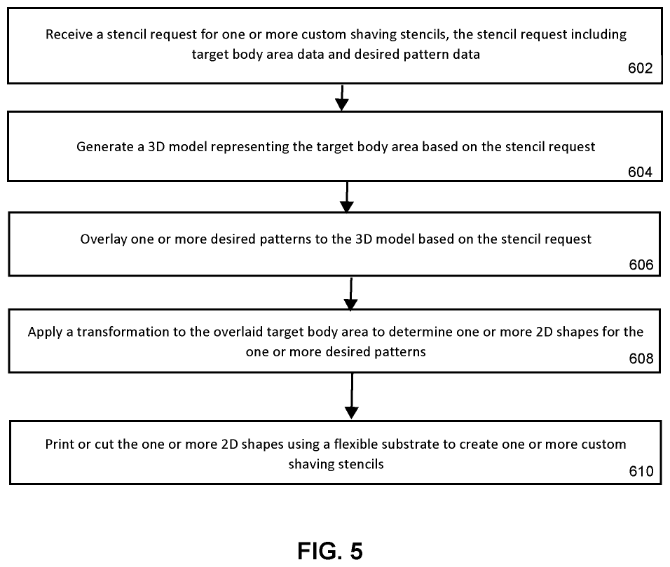

Referring to FIG. 5, a flow diagram of the core steps of a method of manufacturing one or more custom shaving stencils according to the present disclosure is shown.

In a first step 602, the method involves receiving a stencil request for one or more custom shaving stencils, the stencil request including target body area data and desired pattern data. The request itself may originate from a user device such as a mobile phone of an individual using a dedicated application software for requesting custom shaving stencils. Alternatively, the request may originate directly form a manufacturer.

The target body area data includes any and all relevant data about an intended body part to which the stencil will be applied to assist with shaving. This may be data about a human or animal body part, and can be a simple reference to a type of body part on a type of animal, in which case the method would further comprise looking up a matching stored representation of the specified animal type and body part type from a library of stored 3D models or scans.

Alternatively, the target body area data may include its own representation of the target body area, such as for example data relating to a scan of a target body area taken by a user device sending the request. In some examples, a dedicated application software installed on a user's mobile device may provide an interface for enabling a user to scan a target body area, select a desired pattern form a range of options or even create their own desired pattern, and then send the request to a central server over a wireless network which would then process the request.

For example, the mobile device of the user may use the integrated device camera to determine the contours and dimensions of a target body area they wish to shave a pattern into. Alternatively or additionally, the device may be fitted with a LIDAR sensor for determining the contours and dimensions of the target body area.

In such examples, the method may further comprise adding any 3D scans included in the request to a library of stored 3D models.

The desired pattern data contained in the request may indicate one or multiple patterns which the sender desires to be shaved into the target body area. These may be selected by the end user from a pre-determined range of pattern options or could equally be custom drawn shapes.

In a second step 604, the method involves generating a 3D model representing the target body area based on the stencil request.

This step may involve pulling one or more matched 3D models from a library of stored representations or constructing a representation of the target body area in 3D based on scan data received in the request. The end result will be that a set of contours matching the target body area indicated in the request will be formed into a 3D representation, such as a point cloud representation.

Any suitable 3D computer-aided design software may be used in conjunction with the disclosed method.

In a third step 606, the method involves overlaying one or more desired patterns to the 3D model based on the stencil request. The pre-determined or custom patterns contained in the desired pattern data are overlaid onto the 3D model created in the previous step. To form a 3D image of the areas that would be covered by the shaving stencil during shaving.

At this point, a further optional step which may be useful in some examples is the addition of one or more points on the stencil pattern representation to indicate where one or more orientation markings should be placed. These orientation markings help a user determine which way to hold the stencil while placing it on the target body area.

In a fourth step 608, the method involves applying a transformation to the overlaid target body area to determine one or more 2D shapes for the one or more desired patterns, converting the 3D (x, y, z) co-ordinates of the model to planar (u, v) co-ordinates.

There are many suitable methods for converting a 3D object to 2D which can be used at this stage, with the requirement that the surface area of the 2D transformed object equals the surface area of the 3D original.

In a sixth step 610, the method involves printing or cutting the one or more 2D shapes using a flexible substrate to create one or more custom shaving stencils. For example, the determined shape for the requested stencil may be cut out by a CNC machine or other cutting method.

Preferably, the stencil is cut out of a flexible substrate comprising an adhesive layer that can adhere the stencil to the target body area during shaving without requiring pressure to be maintained to hold it in place.

A possible application of the disclosed method is dying the hair covering the target body area instead of/as well as cutting it. Thus, in some examples the flexible substrate may comprise one or more layers for storing dye or another colouring agent. Alternately, the stencil could be applied on the targeted area and a colouring material (dye) could be applied on and around the stencil to colour the hair uncovered by the stencil giving with colour the reverse shape of the stencil.

As mentioned previously, the disclosed method of manufacturing one or more custom shaving stencils may be implemented by a dedicated application software on one or more client devices communicating with a central server over a wireless network.

Furthermore, as mentioned previously, the present disclosure also provides systems and software such as an online store and mobile application for allowing users to see what pre-made stencils are available to purchase and check what those stencils would look like when applied to their own face or other body area to help them choose what to select.

For example, the user may use their mobile phone (see FIG. 7) to access the mobile application and store and select through an interface an option to check out what a stencil would look like on their face. The mobile phone would then use its camera to take a picture of the user's face and analyse their profile—for example it may try to match it with one of the 7 main face shapes and measure the size.

After this step, the app may suggest a stencil that would suit the user's face based on a smart algorithm, or may simply provide a scan over which the user can apply stencils selected from those available in the online store.

This feature, as well as the custom stencil request feature, requires transmission of data over a wireless network architecture (see FIG. 6).

Referring to FIG. 6, there is shown an illustrative network architecture that includes a server based service offering or a cloud based service offering which may be used to implement the method of the present disclosure. The illustrative networked or cloud service 710 is configured to communicate with client devices 718. The illustrative client devices include a personal computer 720, a laptop 722, a tablet computer 724, a smartphone 726, and a display 728 that has a wired connection to a networked computer 730. The clients 718 may be operationally coupled to a wide area network (WAN) such as the Internet with a wireless connection. The wireless clients may be communicatively coupled to the WAN via a Wi-Fi (or Bluetooth) access point 732 that is communicatively coupled to an illustrative modem 734, which is communicatively coupled to the WAN. The wireless clients may also be communicatively coupled to the WAN using a proprietary carrier network that includes illustrative communication tower 736.

Referring to FIG. 7, there is shown the electrical components for an illustrative wireless client device 800. For purposes of this patent, the illustrative wireless device 800 is a multimode wireless device that comprises a first antenna element 802 that is operatively coupled to a duplexer 804, which is operatively coupled to a multimode transmitter module 806, and a multimode receiver module 808.

An illustrative control module 818 comprises a digital signal processor (DSP) 812, a processor 814, and a CODEC 816 that are communicatively coupled to the transmitter 806 and receiver 808. It shall be appreciated by those of ordinary skill in the art that the transmitter module and receiver module are typically paired and may be embodied as a transceiver. The illustrative transmitter 806, receiver 808, or transceiver is communicatively coupled to antenna element 802.

The DSP 812 may be configured to perform a variety of operations such as controlling the antenna 802, the multimode transmitter module 806, and the multimode receiver module 808. The processor 814 is operatively coupled to a responsive input sensor 820 such as a keypad or a touch screen.

The processor 814 is also operatively coupled to a memory 822, a display 824, and a sensor 821. The sensor 821 may be used to determine an indoor and outside location for the illustrative wireless device.

Additionally, the processor 812 is also operatively coupled to the CODEC module 816 that performs the encoding and decoding operations and is communicatively coupled to a speaker 826, and a microphone 828. The CODEC module 816 is also communicatively coupled to the display 824 and provides the encoding and decoding operations for video.

The memory 822 includes two different types of memory, namely, volatile memory 823 and non-volatile memory 825. The volatile memory 823 is computer memory that requires power to maintain the stored information, such as random access memory (RAM). The non-volatile memory 825 can retain stored information even when the wireless communication device 800 is not powered up. Some illustrative examples of non-volatile memory 825 include flash memory, ROM memory, and hard drive memory.

Wireless device 800 may be a mobile handset, mobile phone, wireless phone, portable cell phone, cellular phone, portable phone, a personal digital assistant (PDA), a tablet, a portable media device, a wearable computer, or any type of mobile terminal which is regularly carried by an end user and has all the elements necessary for operation in a wireless communication system. The wireless communications include, by way of example and not of limitation, CDMA, WCDMA, GSM, UMTS, or any other wireless communication system such as wireless local area network (WLAN), Wi-Fi or WiMAX.

It should be understood that the operations described herein may be carried out by any processor. In particular, the operations may be carried out by, but are not limited to, one or more computing environments used to implement the method such as a data center, a cloud computing environment, a dedicated hosting environment, and/or one or more other computing environments in which one or more assets used by the method re implemented; one or more computing systems or computing entities used to implement the method; one or more virtual assets used to implement the method; one or more supervisory or control systems, such as hypervisors, or other monitoring and management systems, used to monitor and control assets and/or components; one or more communications channels for sending and receiving data used to implement the method; one or more access control systems for limiting access to various components, such as firewalls and gateways; one or more traffic and/or routing systems used to direct, control, and/or buffer, data traffic to components, such as routers and switches; one or more communications endpoint proxy systems used to buffer, process, and/or direct data traffic, such as load balancers or buffers; one or more secure communication protocols and/or endpoints used to encrypt/decrypt data, such as Secure Sockets Layer (SSL) protocols, used to implement the method; one or more databases used to store data; one or more internal or external services used to implement the method; one or more backend systems, such as backend servers or other hardware used to process data and implement the method; one or more software systems used to implement the method; and/or any other assets/components in which the method is deployed, implemented, accessed, and run, e.g., operated, as discussed herein, and/or as known in the art at the time of filing, and/or as developed after the time of filing.

As used herein, the terms “computing system”, “computing device”, and “computing entity”, include, but are not limited to, a virtual asset; a server computing system; a workstation; a desktop computing system; a mobile computing system, including, but not limited to, smart phones, portable devices, and/or devices worn or carried by a user; a database system or storage cluster; a switching system; a router; any hardware system; any communications system; any form of proxy system; a gateway system; a firewall system; a load balancing system; or any device, subsystem, or mechanism that includes components that can execute all, or part, of any one of the processes and/or operations as described herein.

As used herein, the terms computing system and computing entity, can denote, but are not limited to, systems made up of multiple: virtual assets; server computing systems; workstations; desktop computing systems; mobile computing systems; database systems or storage clusters; switching systems; routers; hardware systems; communications systems; proxy systems; gateway systems; firewall systems; load balancing systems; or any devices that can be used to perform the processes and/or operations as described herein.

As used herein, the term “computing environment” includes, but is not limited to, a logical or physical grouping of connected or networked computing systems and/or virtual assets using the same infrastructure and systems such as, but not limited to, hardware systems, software systems, and networking/communications systems. Typically, computing environments are either known environments, e.g., “trusted” environments, or unknown, e.g., “untrusted” environments. Typically, trusted computing environments are those where the assets, infrastructure, communication and networking systems, and security systems associated with the computing systems and/or virtual assets making up the trusted computing environment, are either under the control of, or known to, a party.

Unless specifically stated otherwise, as would be apparent from the above discussion, it is appreciated that throughout the above description, discussions utilizing terms such as, but not limited to, “activating”, “accessing”, “adding”, “applying”, “analyzing”, “associating”, “calculating”, “capturing”, “classifying”, “comparing”, “creating”, “defining”, “detecting”, “determining”, , “eliminating”, “extracting”, “forwarding”, “generating”, “identifying”, “implementing”, “obtaining”, “processing”, “providing”, “receiving”, “sending”, “storing”, “transferring”, “transforming”, “transmitting”, “using”, etc., refer to the action and process of a computing system or similar electronic device that manipulates and operates on data represented as physical (electronic) quantities within the computing system memories, resisters, caches or other information storage, transmission or display devices.

Those of skill in the art will readily recognize that the algorithms and operations presented herein are not inherently related to any particular computing system, computer architecture, computer or industry standard, or any other specific apparatus. Various general purpose systems may also be used with programs in accordance with the teaching herein, or it may prove more convenient/efficient to construct more specialized apparatuses to perform the required operations described herein. The required structure for a variety of these systems will be apparent to those of skill in the art, along with equivalent variations. In addition, the present invention is not described with reference to any particular programming language and it is appreciated that a variety of programming languages may be used to implement the teachings of the present invention as described herein, and any references to a specific language or languages are provided for illustrative purposes only and for enablement of the contemplated best mode of the invention at the time of filing.

Unless otherwise defined, all terms (including technical terms) used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

The disclosed embodiments are illustrative, not restrictive. While specific configurations of the method of manufacturing a shaving stencil have been described in a specific manner referring to the illustrated embodiments, it is understood that the present invention can be applied to a wide variety of solutions which fit within the scope and spirit of the claims. There are many alternative ways of implementing the invention.

It is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A method of manufacturing one or more shaving stencils, the method comprising the steps of:
creating a library of 3D models or representations of various human or animal body parts;
selecting a desired body part to create a stencil for;
designing a 3D stencil shaped to create a desired hair pattern for that body part;
applying the 3D stencil to the 3D representation of the selected body part;
unwrapping the 3D stencil to 2D using UV unwrapping to determine one or more 2D stencil shapes; and
printing or cutting the one or more 2D shapes using a flexible substrate to create one or more shaving stencils.

2. A method of manufacturing one or more custom shaving stencils, the method comprising the steps of:
receiving a stencil request for one or more custom shaving stencils, the stencil request including target body area data and desired pattern data;
generating a 3D model representing the target body area based on the stencil request;
overlaying one or more desired patterns to the 3D model based on the stencil request;
applying a transformation to the overlaid target body area to determine one or more 2D shapes for the one or more desired patterns; and
printing or cutting the one or more 2D shapes using a flexible substrate to create one or more custom shaving stencils.

3. A method according to claim 2, wherein the target body area data comprises an indication of a type of human or animal body and an area of the body, and wherein generating the 3D model involves matching the data with a 3D representation stored in a library and using the matched 3D representation to generate the model.

4. A method according to claim 2, wherein the target body area data in the stencil request comprises a 3D scan of a human or animal body part, and wherein generating the 3D model involves using the 3D scan to generate the model.

5. A method according to claim 4, wherein the method further comprises scanning a body part of a human or animal body to determine a set of contours to include in the stencil request.

6. A method according to claim 5, wherein the method further comprises adding each scanned body part to a library of 3D models.

7. A method according to claim 2, wherein the method further comprises determining a point on the one or more 2D shapes and printing one or more markings on the custom shaving stencils corresponding to the points on the one or more 2D shapes.

8. A method according to claim 7, wherein the determination of where to print the markings is based on a target point on the 3D model of the target body area.

9. A method according to claim 2, wherein the step of applying a transformation to convert the model to 2D comprises a UV unwrapping operation.

10. A method according to claim 2, wherein the step of printing or cutting the 2D shapes is a cutting operation performed by a CNC cutting machine.

11. A method according to claim 2, wherein the flexible substrate comprises an adhesive layer.

12. A method according to claim 2, wherein the flexible substrate comprises a layer storing one or more dyes or colouring agents.

13. A virtual representation of a hair pattern created through the use of a 3D stencil or 2D stencil in the method of claim 1.

14. Use of the virtual representation of claim 13 to represent a hair pattern on an avatar.
